(19) United States
(12) Patent Application Publication
(10) Pub. No.: US 2025/0119117 A1
(43) Pub. Date: Apr. 10, 2025

(54) Negative Reactance Synthesizer

(71) Applicant: City University of Hong Kong, Hong Kong (HK)

(72) Inventors: Chi Kong TSE, Hong Kong (HK); Li DING, Hong Kong (HK)

(21) Appl. No.: 18/761,351

(22) Filed: Jul. 2, 2024

Related U.S. Application Data
(60) Provisional application No. 63/588,780, filed on Oct. 9, 2023.

(51) Int. Cl. H03H 11/02; H02M 7/217

(52) U.S. Cl. CPC H03H 11/02; H02M 7/217

(57) ABSTRACT

The present invention provides a negative reactance synthesizer comprising: a DC power source; a first converter configured for shaping an input current under an AC input voltage that has a given peak value and converting a variable DC voltage to a fixed DC voltage; a second converter configured for converting the fixed DC voltage to a stack-up DC voltage being greater than the peak value of the AC input voltage and stacked on the AC input voltage to form the variable DC voltage; a first control circuitry configured to generate a first gate driver signal and a first complementary gate drive signal for controlling the first converter; and a second control circuitry configured to generate a second gate driver signal and a second complementary gate drive signal for controlling the second converter. The present invention provides a simple and low-cost solution to emulate a standalone negative reactance.

### CROSS-REFERENCE TO RELATED APPLICATIONS

The present application claims priority from the U.S. Provisional Patent Application No. 63/588,780 filed 9 Oct. 2023, and the disclosure of which is incorporated herein by reference in its entirety.

### FIELD OF THE INVENTION

The present invention generally relates to synthesis of standalone negative reactance. More specifically the present invention relates to synthesis of standalone negative inductance and standalone negative capacitance.

### BACKGROUND OF THE INVENTION

Compensation is a common technique applied in AC power transmission systems and wireless power transfer (WPT) systems for improving the power factor and efficiency. In practice, compensation is usually achieved by adding a capacitor to counteract the effect of unwanted inductance or adding an inductor to counteract the effect of unwanted capacitance. However, using inductors/capacitors for compensation necessitates additional design considerations which often complicate the design of the system. For power systems, the use of capacitors may change the harmonic impedance of the system, which can be either inductive or capacitive. Moreover, for specific harmonic frequencies, the capacitors may resonate with the system, leading to amplification of harmonic currents, which not only poses risks to the capacitors but also jeopardize the electrical equipment within the power grid. In severe cases, it can cause damages and even disrupt the normal operation of the power grid. For WPT systems, precise compensation by inserting inductors/capacitors can only be achieved at a specific frequency point (resonance frequency) which is affected by variation of parameters, thus necessitating rather complex design processes to maintain performance under practical situations where parameters vary (such as resonant coil inductance and distance between resonant coils). Despite the known drawbacks of applying the abovementioned resonance-based compensation, it remains the only practical solution to counteract unwanted or excessive reactance in the absence of negative reactance.

Some approaches have been tried to synthesize negative valued reactance, which does not exist in the practical world, to directly cancel unwanted reactance. For example, a two-port network, known as gyrator, has been developed to synthesize a small-signal negative reactance. However, gyrator-based circuits can only implement small-signal reactance, which does not behave as a real negative inductance or capacitance. In addition, the gyrator is constructed using operational transconductance amplifiers which are subject to voltage supply limit. A negative reactance realized by gyrator-based circuits is thus only applicable in some signal processing applications, but not for power transfer applications.

Up to now, no standalone negative reactance has been achieved. The closest demonstration of negative reactance was done by indirect verification, where a real reactance was shown to behave with a lesser reactance value in the presence of an additional circuit that merged with the original reactance, thereby indirectly proving the equivalent function of that additional circuit being a negative reactance. Obviously, such an implementation can hardly be applied for applications such as the compensation mentioned above, because the merging of reactance requires the added circuit being part of the original system while in reality unwanted reactance is generated independently from the intrinsic physics of devices, e.g., leakage inductance in a transformer.

### SUMMARY OF THE INVENTION

It is an objective of the present invention to provide a standalone negative reactance synthesizer to solve the aforementioned technical problems.

In accordance with a first aspect of the present invention, a negative reactance synthesizer is provided. The negative reactance synthesizer comprises: a DC power source, a first converter configured for shaping an input current iᵢₙ under an AC input voltage that has a given peak value E and converting a variable DC voltage to a fixed DC voltage Uₒ; a second converter configured for converting the fixed DC voltage Uₒ to a stack-up DC voltage V_{E}; wherein the stack-up DC voltage V_{E} is greater than the peak value E of the AC input voltage and stacked on the AC input voltage to form the variable DC voltage; a first control circuitry configured to generate a first gate driver signal V_{d1} and a first complementary gate drive signal V_{1-d1} for controlling the first converter; and a second control circuitry configured to generate a second gate driver signal V_{d2} and a second complementary gate drive signal V_{1-d2} for controlling the second converter.

In the present invention, considering emulation of power reactance in power electronics circuits that are capable of handling electric power, input impedance of a converter is designed to be a pure resistor to achieve a high input power factor. Appropriate control is adopted to shape the input current to ensure the input current and input voltage to satisfy the required phase difference to obtain a generic negative reactance.

The present invention overcomes the inherent instability of negative reactance due to power imbalance and provides a simple and low-cost solution for emulating a standalone negative reactance. Through arranging the control circuits, the topology can be emulated as a pure negative inductance or a pure negative capacitance. Also, the present invention can realize the cancellation of a positive reactance.

### BRIEF DESCRIPTION OF THE DRAWINGS:

Embodiments of the invention are described in more details hereinafter with reference to the drawings, in which:

FIG. 1 shows a block diagram of a negative reactance synthesizer in accordance with one embodiment of the present invention;

FIG. 2 shows a definition of the system's input impedance;

FIG. 3 shows a circuit diagram of a first converter according to one embodiment of the present invention;

FIG. 4 shows a circuit diagram of a second converter according to one embodiment of the present invention;

FIG. 5 shows the current loop for current shaping control to achieve the required magnitude and phase relationships between input voltage and input current;

FIG. 6 shows a circuit diagram of a first control circuitry according to one embodiment of the present invention;

FIG. 7A shows a circuit diagram of an active-filter for synthesis of standalone negative inductance according to one embodiment of the present invention;

FIG. 7B shows a circuit diagram of an active-filter for synthesis of standalone negative capacitance according to another embodiment of the present invention;

FIG. 8 shows a circuit diagram of the second control circuitry according to one embodiment of the present invention;

FIGS. 9A and 9B show the waveforms of the input voltage and the input current of the synthesized standalone negative inductance, at frequency of 50 Hz and 100 Hz, respectively;

FIG. 10 shows the measured impedance magnitude and phase angle of the synthesized standalone negative inductive impedance for the frequency range from 50 Hz to 400 Hz;

FIG. 11 shows the circuit that is used to verify the use of the synthesized standalone negative inductance to cancel a positive inductance;

FIG. 12A shows the waveforms of the input voltage and the input current when the circuit does not contain the synthesized standalone negative inductance at frequency of 50 Hz;

FIG. 12B shows the waveforms of the input voltage and the input current when the circuit contains the synthesized standalone negative inductance at frequency of 50 Hz;

FIG. 13A shows the waveforms of the input voltage and the input current in the absence of the synthesized negative inductance at frequency of 100 Hz;

FIG. 13B shows the waveforms of the input voltage and the input current in the presence of the synthesized standalone negative inductance at frequency of 100 Hz;

FIGS. 14A and 14B show the waveforms of the input voltage and the input current of the synthesized standalone negative capacitance, at frequency of 50 Hz and 100 Hz, respectively;

FIG. 15 shows the measured impedance magnitude and phase angle of the synthesized standalone negative capacitive impedance in the frequency range from 50 Hz to 400 Hz;

FIG. 16 shows the circuit that is used to verify the use of the synthesized standalone negative capacitance to cancel a positive capacitance;

FIG. 17A shows the waveforms of the input voltage and the input current in the absence of the synthesized standalone negative capacitance at frequency of 50 Hz;

FIG. 17B shows the waveforms of the input voltage and the input current in the presence of the synthesized standalone negative capacitance at frequency of 50 Hz;

FIG. 18A shows the waveforms of the input voltage and the input current in the absence of the synthesized negative capacitance at frequency of 100 Hz; and

FIG. 18B shows the waveforms of the input voltage and the input current in the presence of the synthesized standalone negative capacitance at frequency of 100 Hz.

### DETAILED DESCRIPTION

In the following description, details of the present invention are set forth as preferred embodiments. It will be apparent to those skilled in the art that modifications, including additions and/or substitutions may be made without departing from the scope and spirit of the invention. Specific details may be omitted so as not to obscure the invention; however, the disclosure is written to enable one skilled in the art to practice the teachings herein without undue experimentation.

A standalone negative inductance Lₙ is defined as follows:

$${v}_{in} = {L}_{n} \frac{{di}_{in}}{dt} , \qquad ( 1 )$$

where Lₙ<0, vᵢₙ and iᵢₙ are the input voltage and the input current, respectively.

In the frequency domain, equation (1) can be written as:

$${V}_{in} ( s ) = s \cdot {L}_{n} \cdot {I}_{in} ( s ) , \qquad ( 2 )$$

where s=jω, ω=2πƒᵢₙ, and ƒᵢₙ is the frequency of the input AC voltage.

Equations (1) and (2) indicate that the impedance of the negative inductance rises linearly with the rising frequency while the voltage lags the current by 90°. In other words, the magnitude-frequency response of the negative inductance is same as the positive inductance while the phase-frequency response of the negative inductance is same as the positive capacitance. Therefore, the characteristic of the negative inductance is different from that of the positive capacitance.

A negative capacitance Cₙ is defined as follows:

$${i}_{in} = {C}_{n} \frac{{dv}_{in}}{dt} , \qquad ( 3 )$$

where Cₙ<0, vᵢₙ and iᵢₙ are the input voltage and the input current, respectively.

In the frequency domain, equation (3) can be written as:

$${I}_{in} ( s ) = s \cdot {C}_{n} \cdot {V}_{in} ( s ) , \qquad ( 4 )$$

where s=jω, ω=2πƒᵢₙ, and ƒᵢₙ is the frequency of the input AC voltage.

Equations (3) and (4) indicate that the impedance of the negative capacitance decreases with the rising frequency while the current lags the voltage by 90°. In other words, the magnitude-frequency response of the negative capacitance is same as the positive capacitance while the phase-frequency response of the negative capacitance is same as the positive inductance. Therefore, the characteristic of the negative capacitance is different from that of the positive inductance.

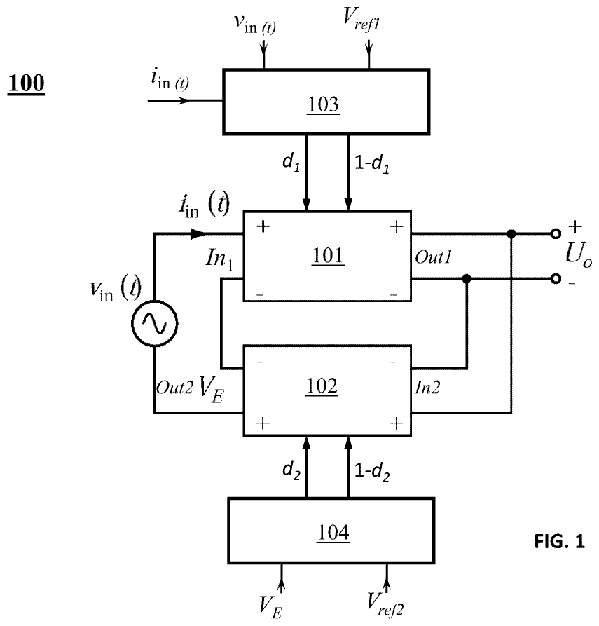

FIG. 1 shows a block diagram of a negative reactance synthesizer 100 in accordance with one embodiment of the present invention. As shown, the negative reactance synthesizer comprises a DC power source (not shown), a first converter 101, a second converter 102, a first control circuitry 103 and a second control circuitry 104.

The DC power source is configured for achieving power balance to avoid abnormal or unstable operation of the synthesizer due to power imbalance caused by power consumption of the AC voltage source in practical situations.

The first converter 101 is configured for shaping an input current iᵢₙ from an AC input voltage with a peak voltage E and converting a variable DC voltage to a fixed DC voltage Uₒ. The first converter has an input port In1 for receiving the AC input voltage and an output port Out1 for delivering the fixed DC voltage Uₒ.

The second converter 102 is configured for converting the fixed DC voltage Uₒ to a stack-up DC voltage V_{E} which is to be stacked on the peak voltage E to form the variable DC voltage. The second converter 102 has an input port In2 for receiving the fixed DC voltage Uₒ and an output port Out2 for delivering the stack-up DC voltage V_{E} which must be higher than E to ensure a positive input voltage for the first converter 101.

In particular, the first converter 101 may be a DC-DC converter capable of converting a variable DC voltage to a fixed DC voltage, and have a voltage conversion ratio k₁ constrained by:

$$\frac{{U}_{o}}{{V}_{E} + E} \leq {k}_{1} \leq \frac{{U}_{o}}{{V}_{E} - E} . \qquad ( 5 )$$

The second converter 102 may be a DC-DC converter capable of converting a fixed DC voltage to another fixed DC voltage, and have a voltage conversion ratio k₂ constrained by:

$${k}_{2} = \frac{{V}_{E}}{{U}_{O}} . \qquad ( 6 )$$

The constraints on the two conversion ratios (the choice of DC-DC converters) depend on the value of Uₒ and there are four different cases. If V_{E}+E>V_{E}>V_{E}−E>Uₒ, the first converter acts as a buck-type converter while the second converter acts as a boost-type converter. If V_{E}+E>V_{E}>Uₒ>V_{E}−E, the first converter acts as a buck/boost-type converter while the second converter acts as a boost-type converter. If V_{E}+E>Uₒ>V_{E}>V_{E}−E, the first converter acts as a buck/boost-type converter while the second converter acts as a buck-type converter. If Uₒ>V_{E}+E>V_{E}>V_{E}−E, the first converter acts as a boost-type converter while the second converter acts as a buck-type converter.

For example, when E is 5 V, V_{E} is 10 V and Uₒ is 20 V, the first converter 101 is configured to be a boost converter and the second converter 102 is configured to be a buck converter.

The first control circuitry 103 is configured to generate a first gate driver signal V_{d1} with a duty cycle of d₁ and a first complementary gate drive signal V_{1-d1} with a duty cycle of 1−d₁ for controlling the first converter.

The second control circuitry 104 configured to generate a second gate driver signal V_{d2} with a duty cycle of d₂ and a second complementary gate drive signal V_{1-d2} with a duty cycle of 1−d₂ for controlling the second converter.

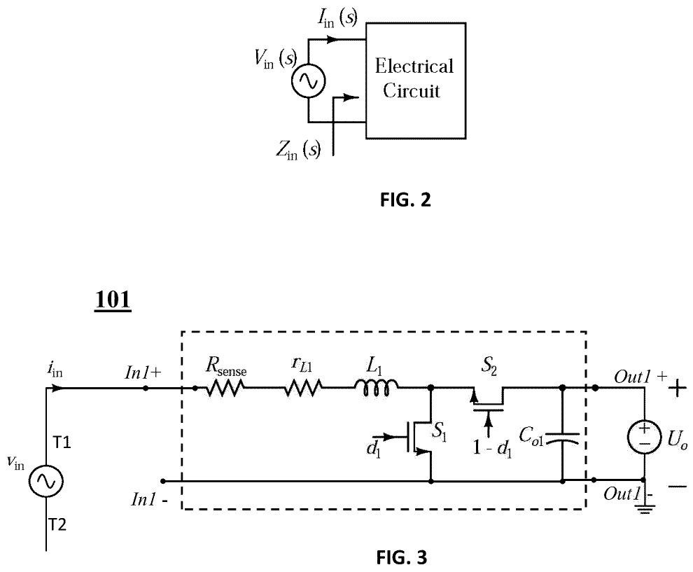

FIG. 2 shows a definition of the system's input impedance. The impedance observed from the terminals of a given circuit is defined as the ratio of the voltage across the terminals and the current flowing into and out of the terminals. In the frequency domain, the impedance can be expressed as:

$${Z}_{in} ( s ) = \frac{{V}_{in} ( s )}{{I}_{in} ( s )} , \qquad ( 7 )$$

where Vᵢₙ(s) and Iᵢₙ(s) are the input voltage and the input current, respectively. Thus, in this representation, Zᵢₙ(s) is the impedance to be synthesized.

The first and second converters 101 and 102 can be either isolated DC-DC converters or non-isolated DC-DC converters.

FIG. 3 shows a circuit diagram of the first converter 101 according to one embodiment of the present invention. Referring to FIG. 3, the first converter 101 comprises: a sampling resistor Rₛₑₙₛₑ having a first end connected to a positive terminal In1+ of the input port of the first converter; a limiting resistor r_{L1} having a first end connected to a second end of the sampling resistor Rₛₑₙₛₑ; a inductor L₁ having a first end connected to a second end of the limiting resistor r_{L1}; a first field effect transistor S₁ having a gate for receiving the first gate driver signal V_{d1}, a drain connected to the second end of the inductor L₁, a source connected to a negative terminal In1− of the input port of the first converter; a second field effect transistor S₂ having a gate for receiving the first complementary gate drive signal V_{1-d1}, a drain connected to a positive terminal Out1+ of the output port of the first converter, and a source connected to the second end of the inductor L₁; and a first output coupling capacitor Cₒ₁ having a first end connected to the positive terminal Out1+ of the output port of the first converter and a second end connected to a negative terminal Out1− of the output port of the first converter.

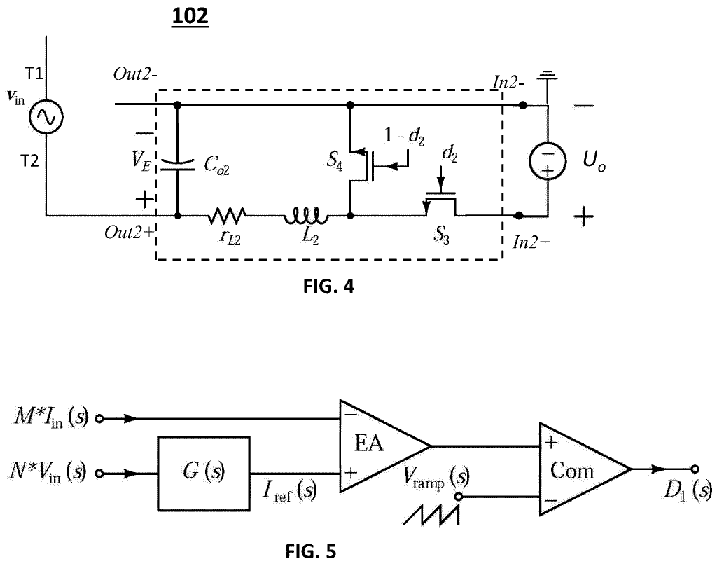

FIG. 4 shows a circuit diagram of the second converter 102 according to one embodiment of the present invention. Referring to FIG. 4, the second converter 102 comprises: a third field effect transistor S₃ having a gate for receiving the second gate driver signal V_{d2}, a drain connected to the positive terminal In2+ of the input port of the second converter; a fourth field effect transistor S₄ having a gate for receiving the second complementary gate drive signal V_{1-d2}, a drain connected to a source of the third field effect transistor S₃, and a source connected to the negative terminal In2− of the input port of the second converter; a inductor L₂ having a first end connected to the source of the third field effect transistor S₃ and the drain of the fourth field effect transistor S₄; a limiting resistor r_{L2} having a first end connected to a second end of the inductor L₂ and a second end connected to a positive terminal Out2+ of the output port of the second converter; and a second output coupling capacitor Cₒ₂ having a first end connected to the positive terminal Out2+ of the output port of the second converter and a second end connected to the negative terminal Out2− of the output port of the second converter. The positive terminal In2+ of the input port of the second converter is connected to the positive terminal Out1+ of the output port of the first converter. The negative terminal In2− of the input port of the second converter is connected to the negative terminal Out1− of the output port of the first converter. The negative terminal Out2− of the output port of the second converter is connected to the negative terminal In1− of the input port of the first converter.

FIG. 5 shows the current loop for current shaping control to achieve the required magnitude and phase relationships between input voltage and input current. The current reference i_{ref} for shaping the input current iᵢₙ should be derived from the input AC voltage vᵢₙ. In the complex frequency domain, the relationship between i_{ref} and vᵢₙ can be expressed as:

$${I}_{ref} ( s ) = N \cdot {V}_{in} ( s ) \cdot G ( s ) , \qquad ( 8 )$$

where N is the sample gain of the input voltage, and G(s) is the transfer function from the sampled input voltage to the reference value of the current loop.

If the sampled current M·iᵢₙ can follow the reference signal i_{ref} which is related to vᵢₙ, the relationship between the sampled current and the reference signal can be written as follows:

$$M \cdot {I}_{in} ( s ) = K ( s ) \cdot {I}_{ref} ( s ) , \qquad ( 9 )$$

where M is the sample gain of the input current.

In general, K(s) depends on the converter response. However, if the bandwidth of the converter response is much higher than that of the applied voltage vᵢₙ, K(s) can be assumed to be a constant equal to a constant value K, i.e., iᵢₙ is proportional to i_{ref}.

Combining equations (7), (8) and (9), the relationship between the input parameters (input voltage and input current) and the control signals is:

$$G ( s ) = \frac{M}{N \cdot K \cdot Z ( s )} . \qquad ( 10 )$$

The first and second control circuitries 103 and 104 may be implemented using general purpose or specialized analog devices or/and computing devices.

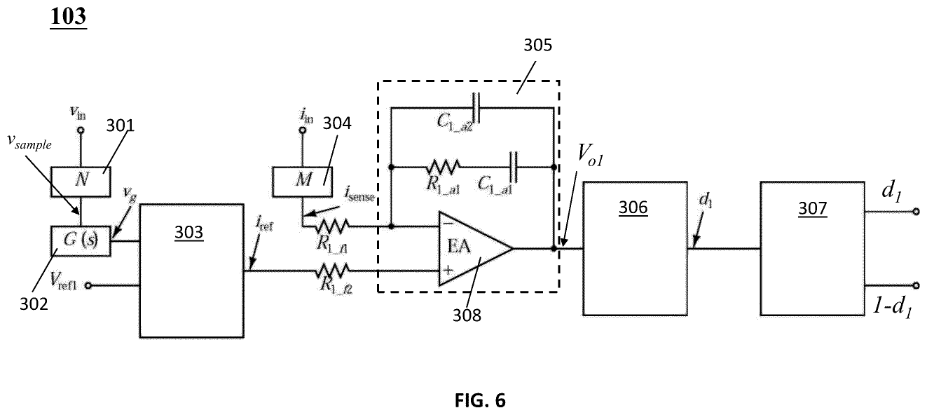

FIG. 6 shows a circuit diagram of the first control circuitry 103 according to one embodiment of the present invention. As shown, the first control circuitry 103 comprises: a voltage sampler 301 having a gain N and configured to sample the input AC voltage Vᵢₙ to generate a sampled voltage vₛₐₘₚₗₑ; an active-filter 302 having a transfer function G(s) and configured to determine a type of reactance to be synthesized and generate an input analog signal V_{g} according to the sampled voltage vₛₐₘₚₗₑ; a multiplier 303 configured to generate a control signal i_{ref} by multiplying the input analog signal V_{g} with a first reference signal V_{ref1}; a current sensor 304 having a gain M and configured to sense the input current iᵢₙ to generate a sensed current iₛₑₙₛₑ; a current amplifier 305 configured to amplify a difference between the sensed current iₛₑₙₛₑ and the control signal i_{ref}, to generate a first output signal Vₒ₁; a first controller 306 configured to generate a first gate driver signal V_{d1} based on the first output signal Vₒ₁; and a first driver 307 configured to generate a first complementary gate drive signal V_{1-d1} based on the first gate driver signal V_{d1}.

The current amplifier 305 comprises: an error amplifier 308 having a positive input port, a negative input port and an output port; a resistor R_{1_a1} having a first end connected to the negative input port of the error amplifier 308; a capacitor C_{1_a1} having a first end connected to a second end of the resistor R_{1_a1} and a second end connected to the output port of the error amplifier 308; and a capacitor C_{1_a2} having a first end connected to the negative input port of the error amplifier 308 and a second end connected to the output port of the error amplifier 308.

The first control circuitry 103 further comprises a resistor R_{1_f1} connected between the current sensor 304 and a negative input port of the current amplifier 305; and a resistor R_{1_f2} connected between the multiplier 303 and a positive input port of the current amplifier 305.

The impedance of a standalone negative inductance may be expressed as:

$$Z ( s ) = s \cdot {L}_{n} , \qquad ( 11 )$$

where Lₙ is the negative inductance to be synthesized and Lₙ<0.

Combining equations (10) and (11), the required G(s) is:

$$G ( s ) = \frac{M}{s \cdot N \cdot K \cdot {L}_{n}} . \qquad ( 12 )$$

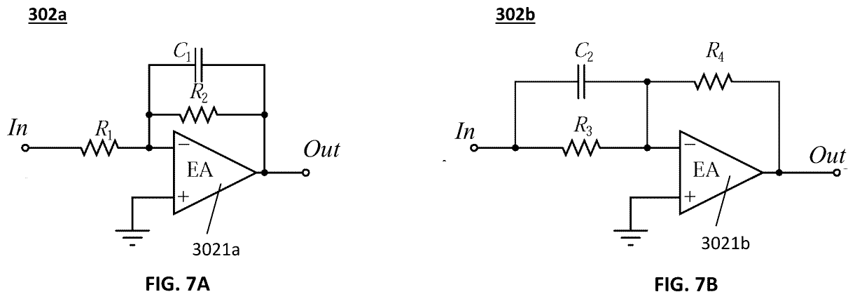

FIG. 7A shows a circuit diagram of an active-filter 302a for synthesis of standalone negative inductance according to one embodiment of the present invention. As shown, the active-filter 302a has an input port and an output port, and comprises: an error amplifier 3021a having a positive input port, a negative input port and an output port; a resistor R₁ having a first end connected to the input port of the active-filter 302a and a second end connected to the negative input port of the error amplifier; a resistor R₂ having a first end connected to the negative input port of the error amplifier and a second end connected to the output port of the error amplifier; and a capacitor C₁ connected in parallel with the resistor R₂.

Suppose the values of C₁ and R₂ satisfy:

$$\vert s \cdot {C}_{1} \cdot {R}_{2} \vert ≫ 1. \qquad ( 13 )$$

Then, G(s) can be written as:

$$G ( s ) \approx - \frac{1}{s \cdot {C}_{1} \cdot {R}_{1}} . \qquad ( 14 )$$

Therefore, the value of the synthesized standalone negative inductance (Lₙ) can be written as:

$${L}_{n} = - \frac{M \cdot {C}_{1} \cdot {R}_{1}}{N \cdot K} \qquad ( 15 )$$

The impedance of a standalone negative capacitance may be expressed as:

$$Z ( s ) = \frac{1}{s \cdot {C}_{n}} , \qquad ( 16 )$$

where Cₙ is the negative capacitance to be synthesized and Cₙ<0.

Combining equations (10) and (11), the required G(s) is:

$$G ( s ) = \frac{s \cdot {C}_{n} \cdot M}{N \cdot K} . \qquad ( 17 )$$

FIG. 7B shows a circuit diagram of an active-filter 302b for synthesis of standalone negative capacitance according to another embodiment of the present invention. As shown, the active-filter 302b has an input port and an output port, and comprises: an error amplifier 3021b having a positive input port, a negative input port and an output port; a resistor R₃ having a first end connected to the input port of the active-filter 302b and a second end connected to the negative input port of the error amplifier; a resistor R₄ having a first end connected to the negative input port of the error amplifier and a second end connected to the output port of the error amplifier; and a capacitor C₂ connected in parallel with the resistor R₃.

Suppose the values of C₂ and R₃ satisfy:

$$\vert s \cdot {C}_{2} \cdot {R}_{3} \vert ≫ 1. \qquad ( 18 )$$

Then, G(s) can be written as:

$$G ( s ) \approx - s \cdot {C}_{2} \cdot {R}_{4} . \qquad ( 19 )$$

Therefore, the value of the synthesized negative capacitance (Cₙ) can be written as:

$${C}_{n} = - \frac{{C}_{2} \cdot {R}_{4} \cdot N \cdot K}{M} . \qquad ( 20 )$$

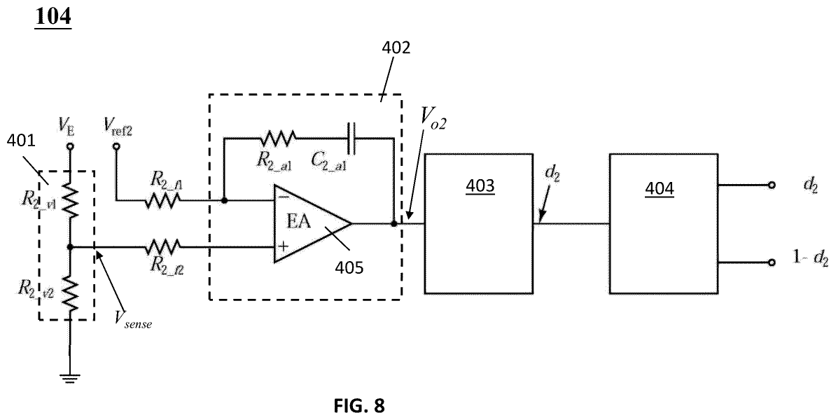

FIG. 8 shows a circuit diagram of the second control circuitry 104 according to one embodiment of the present invention. Referring to FIG. 8, the second control circuitry 104 comprises: a voltage sensor 401 configured to sense the stack-up DC voltage V_{E} and generate a sensed voltage Vₛₑₙₛₑ proportional to the stack-up DC voltage V_{E}; a voltage amplifier 402 configured to amplify a difference between the sensed voltage Vₛₑₙₛₑ and a second reference signal V_{ref2}, and generate a second output signal Vₒ₂; a second controller 403 configured to generate a second gate driver signal V_{d2} based on the second output signal Vₒ₂; and a second driver 404 configured to generate a second complementary gate drive signal V_{1-d2} from the second gate driver signal V_{d2}.The voltage sensor 401 comprises: a first sensing resistor R_{2_v1} having a first end connected to the positive terminal of the output port of the second converter; and a second sensing resistor R_{2_v2} having a first end connected to a second end of the first sensing resistor R_{2_v1}. In other words, the first sensing resistor R_{2_v1} and the second sensing resistor R_{2_v2} are connected in series. The sensed voltage Vₛₑₙₛₑ is generated at a connection node between the first sensing resistor R_{2_v1} and the second sensing resistor R_{2_v2}.

The voltage amplifier 402 comprises: an error amplifier 405 having a positive input port, a negative input port and an output port; a resistor R_{2_a1} having a first end connected to the negative input port of the error amplifier 405; and a capacitor C_{2_a1} having a first end connected to a second end of the resistor R_{2_a1} and a second end connected to the output port of the error amplifier 405.

The second control circuitry further comprises: a resistor R_{2_f1} connected between the reference voltage V_{ref2} and a negative input port of the voltage amplifier; and a resistor R_{2_f2} connected between the voltage sensor and a positive input port of the voltage amplifier.

### EVALUATION OF PERFORMANCE

According to the embodiment of the present invention, the prototypes of a negative inductance synthesizer and a negative capacitance synthesizer have been built for evaluation. The key parameters are listed in Table I.

TABLE I
Key Parameters of Evaluation Prototypes

| Design Parameter | Value | |
|---|---|---|
| Peak of the input AC voltage vᵢₙ | 5 | V |
| Frequency of the input AC voltage fᵢₙ | 50 Hz/100 Hz | |
| Rₛₑₙₛₑ | 0.3 | Ω |
| r_{L1} | 0.1 | Ω |
| r_{L2} | 0.1 | Ω |
| L₁ | 470 | μH |
| L₂ | 680 | μH |
| Cₒ₁ | 1000 | μF |
| Cₒ₂ | 1000 | μF |
| Operating frequency of converter 1 f₁ | 20 | kHz |
| Operating frequency of converter 2 f,₂ | 20 | kHz |
| N | 1/6 | |
| R₁ | 51 | kΩ |
| R₂ | 200 | kΩ |
| R₃ | 1.5 | MΩ |
| R₄ | 1 | kΩ |
| R₁_{_{—}}_{f1} | 510 | Ω |
| R₁_{_{—}}_{f2} | 510 | Ω |
| R₁_{_{—}}ₐ₁ | 10 | kΩ |
| R₂_{_{—}}ᵥ₁ | 10 | kΩ |
| R₂_{_{—}}ᵥ₂ | 10 | kΩ |
| R₂_{_{—}}_{f1} | 51 | kΩ |
| R₂_{_{—}}_{f2} | 51 | kΩ |
| R₂_{_{—}}ₐ₁ | 4.7 | kΩ |
| C₁ | 1 | μF |
| C₂ | 100 | nF |
| C₁_{_{—}}ₐ₁ | 2.2 | nF |
| C₁_{_{—}}ₐ₂ | 0.22 | nF |
| C₂_{_{—}}ₐ₁ | 1 | μF |
| V_{E} | 10 | V |
| V_{ref1} | 5 | V |
| V_{ref2} | 5 | V |
| Uₒ | 20 | V |

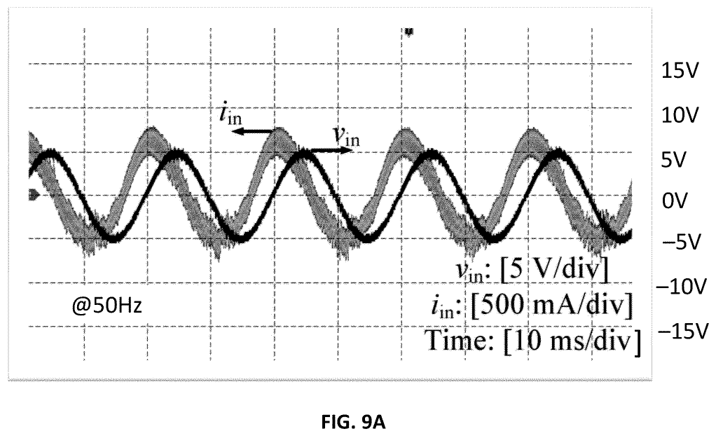

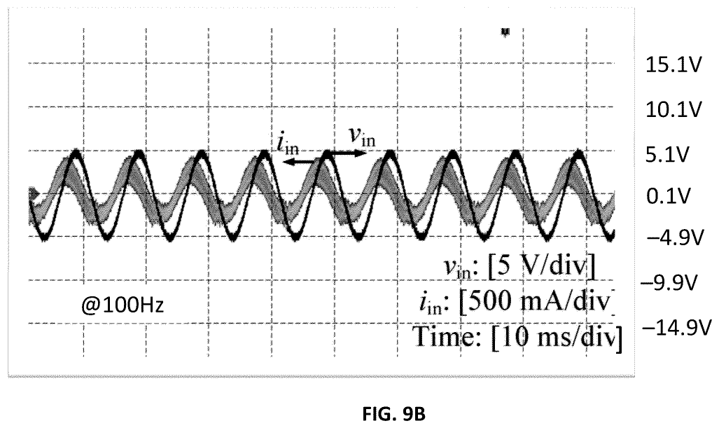

FIGS. 9A and 9B show the relevant waveforms of a synthesized standalone negative inductance. The value of the synthesized standalone negative inductance is −29 mH. FIG. 9A shows the input voltage and the input current when the frequency of the input voltage is 50 Hz, while FIG. 9B shows the input voltage and the input current when the frequency of the input voltage is 100 Hz. The peak value of the input voltage in both cases are 5 V. It can be observed that the phase of input current leads the phase of input voltage by 90° in both cases.

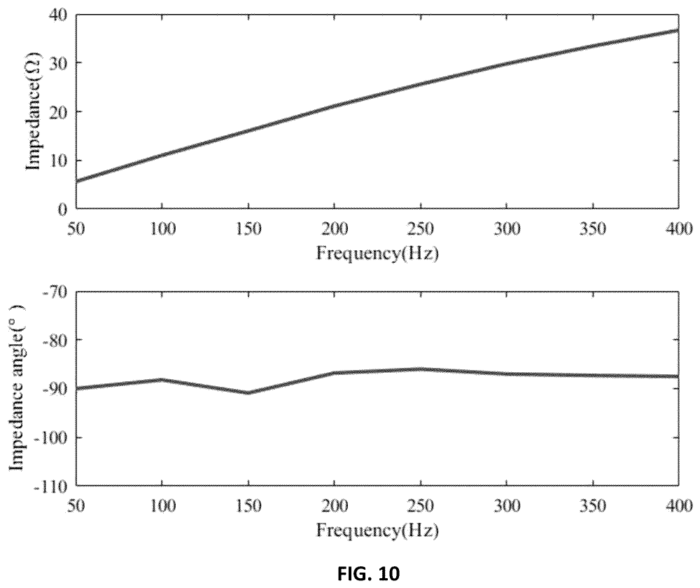

FIG. 10 shows the measured impedance magnitude and phase angle of the synthesized standalone negative inductive impedance for the frequency range from 50 Hz to 400 Hz. The test input voltage peak value is 5 V. From FIG. 10, it can be observed that the magnitude of the impedance increases with the increasing frequency while the input current keeps leading the input voltage by nearly 90° despite variation of the frequency, which is in line with the definition of the negative inductance.

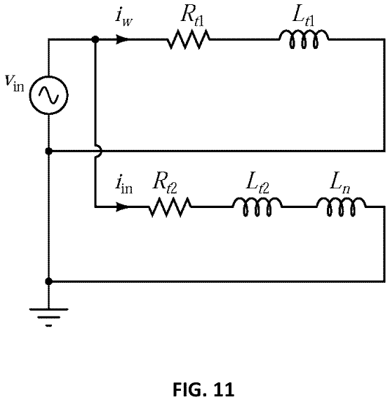

FIG. 11 shows the circuit that is used to verify the use of the synthesized standalone negative inductance to cancel a positive inductance. In FIG. 11, both Rₜ₁ and Rₜ₂ are 11 Ω, and both Lₜ₁ and Lₜ₂ are 40 mH. Lₙ is the synthesized standalone negative inductance with a value of −29 mH. The peak value and the frequency of the input voltage are 5 V and 50 Hz, respectively.

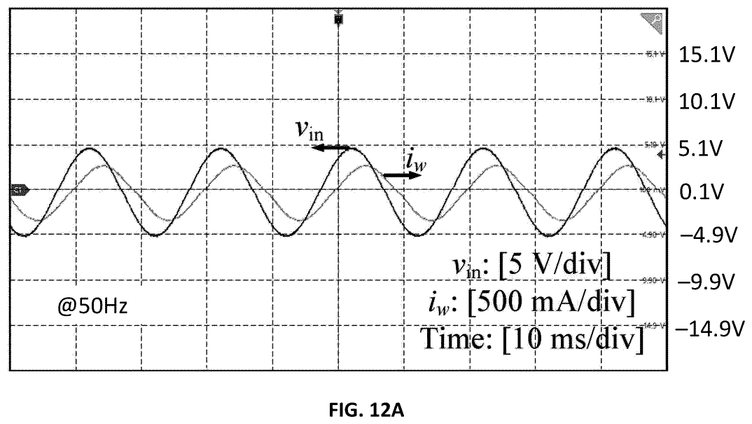

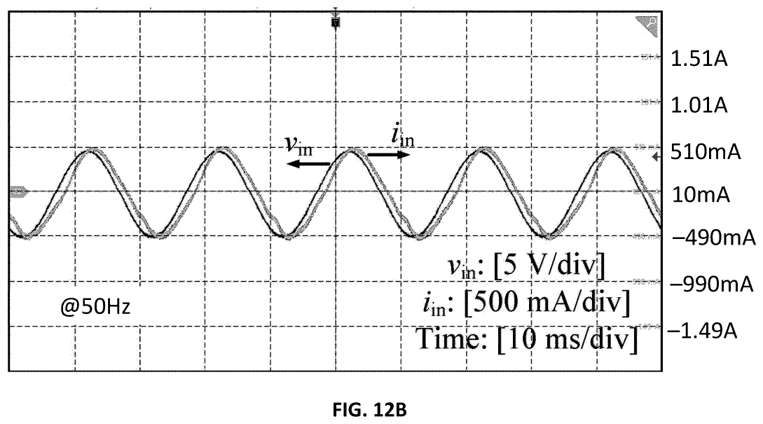

FIG. 12A shows the waveforms of the input voltage and the input current when the circuit does not contain the synthesized standalone negative inductance Lₙ. vᵢₙ represents the input voltage. i_{w} represents the input current in the absence of Lₙ. When Lₙ is not added to the circuit, the magnitude of the impedance of the circuit is 16.7 Ω and the argument is 48.8°. From FIG. 12A, the peak value of i_{w} is about 0.26 A, and vᵢₙ leads i_{w} by nearly 49°, which is consistent with the theoretical analysis.

FIG. 12B shows the waveforms of the input voltage and the input current when the circuit contains the synthesized standalone negative inductance Lₙ. vᵢₙ represents the input voltage. iᵢₙ represents the input current in the presence of Lₙ. When Lₙ is connected in series with Rₜ₂ and Lₜ₂, the magnitude of the impedance of the circuit is 11.5 Ω and the argument is 17.4° since a large part of the reactance of Lₜ₂ has been canceled by Lₙ. From FIG. 12B, the peak value of iᵢₙ is about 0.45 A. vᵢₙ leads iᵢₙ by about 17°. This demonstrates that the synthesized standalone negative inductance can cancel the positive inductance successfully.

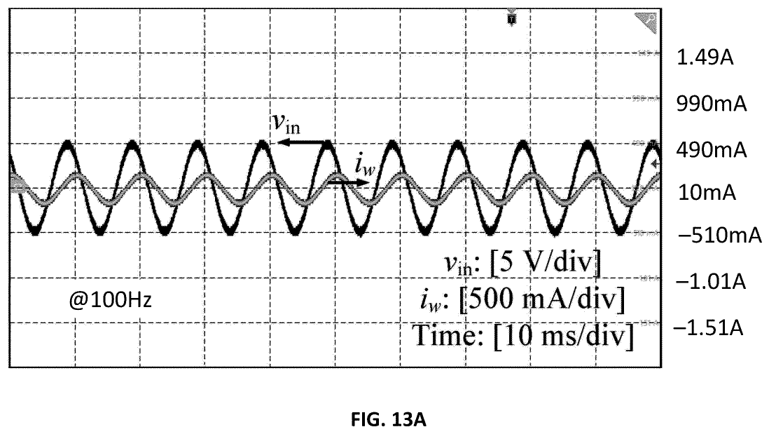

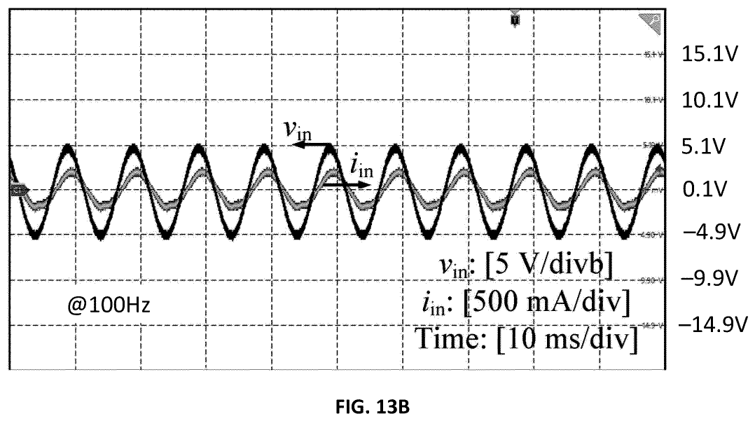

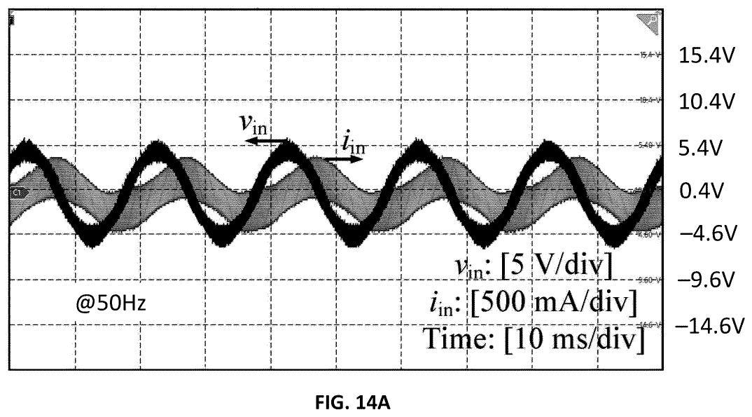

FIGS. 13A and 13B show the waveforms of the input voltage and the input current when using the synthesized standalone negative inductance to cancel a positive inductance. The verification circuit and the values of all inductors are the same as given in FIG. 11. Both Rₜ₁ and Rₜ₂ are 20 Ω in this case, and Lₙ is the synthesized standalone negative inductance which is −29 mH. The peak and the frequency of the input voltage are 5 V and 100 Hz, respectively.

FIG. 13A shows the waveforms of the input voltage and the input current in the absence of the synthesized negative inductance Lₙ. vᵢₙ represents the input voltage. i_{w} represents the input current in the presence of Lₙ. When Lₙ is not added to the circuit, the magnitude of the impedance of the circuit is 32.1 Ω and the argument is 51.5°. From FIG. 13A, the peak value of i_{w} is about 0.15 A, and vᵢₙ leads i_{w} by nearly 50°, which is consistent with the theoretical analysis.

FIG. 13B shows the waveforms of the input voltage and the input current in the presence of the synthesized standalone negative inductance Lₙ. vᵢₙ represents the input voltage. iᵢₙ represents the input current in the presence of Lₙ. When Lₙ is connected in series with Rₜ₂ and Lₜ₂, the magnitude of the impedance of the circuit is 21.2 Ω and the argument is 19° since a large part of the reactance of Lₜ₂ has been canceled by Lₙ. From FIG. 13B, the peak value of iᵢₙ is about 0.23 A. vᵢₙ leads iᵢₙ by 19°. This demonstrates that the proposed synthesized standalone negative inductance can cancel the positive inductance successfully.

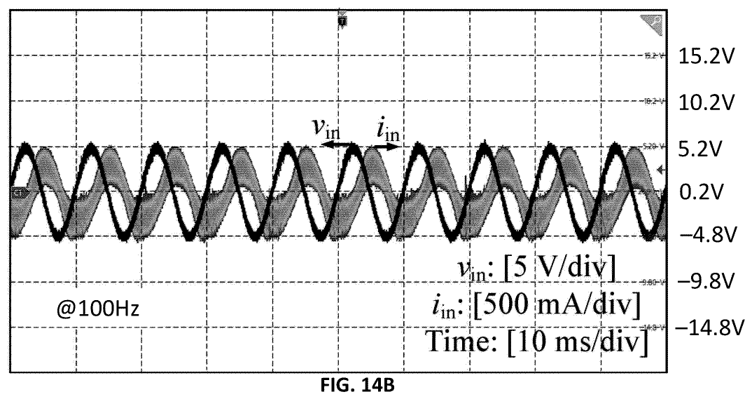

FIGS. 14A and 14B show the relevant waveforms of the synthesized standalone negative capacitance. The value of the synthesized standalone negative capacitance is −140 μF. FIG. 14A shows the input voltage and the input current when the frequency of the input voltage is 50 Hz, while FIG. 14B shows the input voltage and the input current when the frequency of the input voltage is 100 Hz. The peak value of the input voltage in both cases are 5 V. It can be observed that the input voltage leads the input current by 90° in both cases.

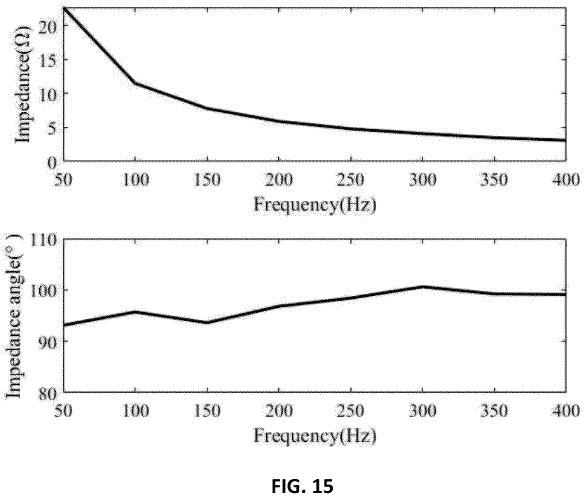

FIG. 15 shows the measured impedance magnitude and phase angle of the synthesized standalone negative capacitive impedance for the frequency range from 50 Hz to 400 Hz. The test input voltage peak is 5 V. From FIG. 15, it can be observed that the magnitude of the impedance decreases with increasing frequency while the input voltage keeps leading the input current by about 90° despite variation of the frequency, which is in line with the definition of the negative capacitance.

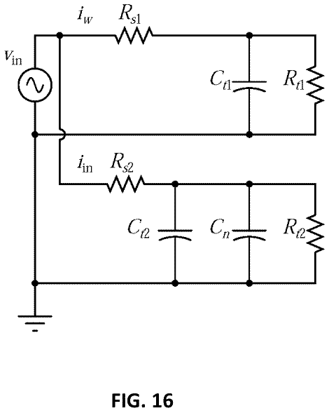

FIG. 16 shows the circuit that is used to verify the use of the synthesized standalone negative capacitance to cancel a positive capacitance. In FIG. 16, both Rₜ₁ and Rₜ₂ are 25 Ω, both Rₛ₁ and Rₛ₂ are 2 Ω, and both Cₜ₁ and Cₜ₂ are 147 μF. Cₙ is the synthesized standalone negative capacitance with a value of −140 μF. The peak value and the frequency of the input voltage are 5 V and 50 Hz, respectively.

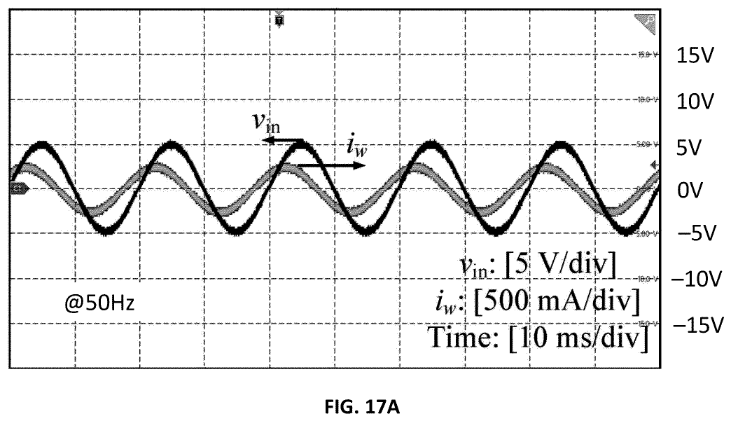

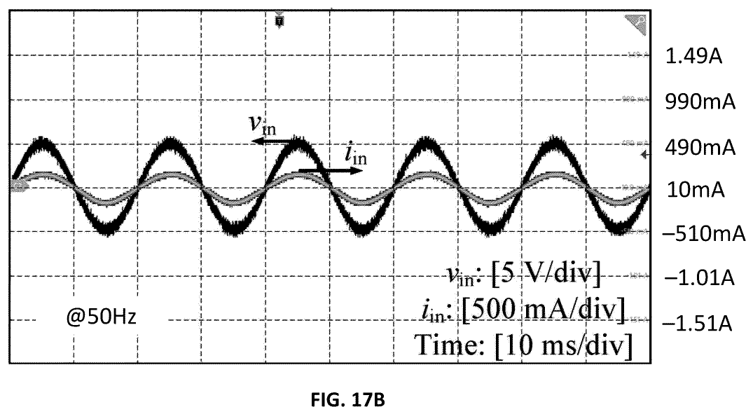

FIG. 17A shows the waveforms of the input voltage and the input current in the absence of the synthesized standalone negative capacitance Cₙ. vᵢₙ represents the input voltage. i_{w} represents the input current in the absence of Cₙ. When Cₙ is not added to the circuit, the magnitude of the impedance of the circuit is about 17.7 Ω and the argument is −45°. From FIG. 17A, the peak value of i_{w} is about 0.29 A, and i_{w} leads vin by nearly 45°, which is consistent with the theoretical analysis.

FIG. 17B shows the waveforms of the input voltage and the input current in the presence of the synthesized standalone negative capacitance Cₙ. vᵢₙ represents the input voltage. iᵢₙ represents the input current in the presence of Cₙ. When Cₙ is connected in parallel with Rₜ₂ and Cₜ₂, the magnitude of the impedance of the circuit is about 27 Ω and the argument is −3° since a large part of the reactance of Cₜ₂ has been canceled by Cₙ. From FIG. 17B, the peak value of iᵢₙ is about 0.2 A, vᵢₙ and iᵢₙ are almost in phase. This demonstrates that the proposed synthesized standalone negative capacitance can cancel the positive capacitance successfully.

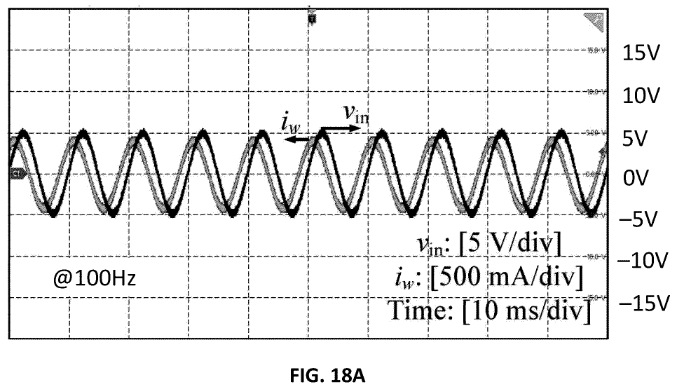

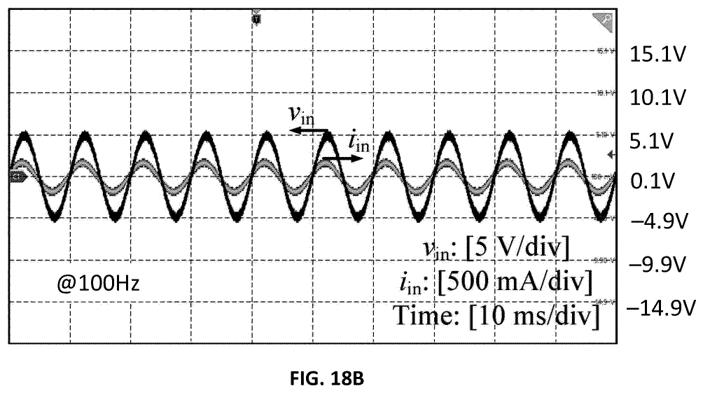

FIGS. 18A and 18B show the waveforms of the input voltage and the input current when using the synthesized standalone negative capacitance to cancel a positive capacitance. The verification circuit and the values of all resistors and capacitors are the same as given in FIG. 16. Cₙ is the synthesized standalone negative capacitance with a value of −140 μF. The peak value and the frequency of the input voltage are 5 V and 100 Hz, respectively.

FIG. 18A shows the waveforms of the input voltage and the input current in the absence of the synthesized standalone negative capacitance Cₙ. vᵢₙ represents the input voltage. i_{w} represents the input current in the absence of Lₙ. When Cₙ is not added to the circuit, the magnitude of the impedance of the circuit is 10.9 Ω and the argument is −57°. From FIG. 18A, the peak value of i_{w} is about 0.48 A, and i_{w} leads vin by nearly 55°, which is consistent with the theoretical analysis.

FIG. 18B shows the waveforms of the input voltage and the input current in the presence of the synthesized standalone negative capacitance Cₙ. vᵢₙ represents the input voltage. iᵢₙ represents the input current in the presence of Cₙ. When Cₙ is connected in parallel with Rₜ₂ and Cₜ₂, the magnitude of the impedance of the circuit is 27 Ω and the argument is −6° since a large part of the reactance of Cₜ₂ has been canceled by Cₙ. From FIG. 18B, the peak value of iᵢₙ is about 0.2 A, vᵢₙ and iᵢₙ are almost in phase. This demonstrates that the proposed synthesized standalone negative capacitance can cancel the positive capacitance successfully.

While the present disclosure has been described and illustrated with reference to specific embodiments thereof, these descriptions and illustrations are not limited. The illustrations may not necessarily be drawn to scale. There may be distinctions between the artistic renditions in the present disclosure and the actual apparatus due to manufacturing processes and tolerances. There may be other embodiments of the present disclosure which are not specifically illustrated. Modifications may be made to adapt a particular situation, material, composition of matter, method, or process to the objective and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limited.

What is claimed is:

1. A negative reactance synthesizer, comprising:
a DC power source,
a first converter configured for shaping an input current under an AC input voltage that has a given peak value E and converting a variable DC voltage to a fixed DC voltage Uₒ;
a second converter configured for converting the fixed DC voltage Uₒ to a stack-up DC voltage V_{E}, wherein the stack-up DC voltage V_{E} is greater than the peak value E of the AC input voltage and stacked on the AC input voltage to form the variable DC voltage;
a first control circuitry configured to generate a first gate driver signal and a first complementary gate drive signal for controlling the first converter; and
a second control circuitry configured to generate a second gate driver signal and a second complementary gate drive signal for controlling the second converter; and
wherein:
the first converter acts as a buck-type converter and the second converter acts as a boost-type converter when a condition V_{E}+E>V_{E}>V_{E}−E>Uₒ is fulfilled;
the first converter acts as a buck/boost-type converter and the second converter acts as a boost-type converter when a condition V_{E}+E>V_{E}>Uₒ>V_{E}−E is fulfilled;
the first converter acts as a buck/boost-type converter and the second converter acts as a buck-type converter when a condition V_{E}+E>Uₒ>V_{E}>V_{E}−E is fulfilled; or
the first converter acts as a boost-type converter and the second converter acts as a buck-type converter when a condition Uₒ>V_{E}+E>V_{E}>V_{E}−E is fulfilled.

2. The negative reactance synthesizer of claim 1, wherein the first converter has an input port for receiving the AC input voltage and an output port for delivering the fixed DC voltage Uₒ; and the first converter comprises:
a sampling resistor Rₛₑₙₛₑ having a first end connected to a positive terminal of the input port of the first converter;
a limiting resistor r_{L1} having a first end connected to a second end of the sampling resistor Rₛₑₙₛₑ;
an inductor L₁ having a first end connected to a second end of the limiting resistor r_{L1};
a field effect transistor S₁ having a gate for receiving the first gate driver signal, a drain connected to the second end of the inductor L₁, a source connected to a negative terminal of the input port of the first converter;
a field effect transistor S₂ having a gate for receiving the first complementary gate drive signal, a drain connected to a positive terminal of the output port of the first converter, and a source connected to the second end of the inductor L₁; and
an output coupling capacitor Cₒ₁ having a first end connected to the positive terminal of the output port of the first converter and a second end connected to a negative terminal of the output port of the first converter.

3. The negative reactance synthesizer of claim 1, wherein the second converter has an input port for receiving the fixed DC voltage Uₒ and an output port for delivering the stack-up DC voltage V_{E}; and the second converter comprises:
a field effect transistor S₃ having a gate for receiving the second gate driver signal, a drain connected to a positive terminal of the input port of the second converter;
a field effect transistor S₄ having a gate for receiving the second complementary gate drive signal, a drain connected to a source of the field effect transistor S₃, and a source connected to a negative terminal of the input port of the second converter;
an inductor L₂ having a first end connected to the source of the field effect transistor S₃ and the drain of the field effect transistor S₄;
a limiting resistor r_{L2} having a first end connected to a second end of the inductor L₂ and a second end connected to a positive terminal of the output port of the second converter; and
an output coupling capacitor Cₒ₂ having a first end connected to the positive terminal of the output port of the second converter and a second end connected to a negative terminal of the output port of the second converter.

4. The negative reactance synthesizer of claim 1, wherein the first control circuitry comprises:
a voltage sampler having a gain N and configured to sample the input AC voltage to generate a sampled voltage;
an active-filter having a transfer function and configured to determine a type of reactance to be synthesized and generate an input analog signal according to the sampled voltage;
a multiplier configured to generate a control signal by multiplying the input analog signal with a first reference signal;
a current sensor having a gain M and configured to sense the input current to generate a sensed current;
a current amplifier configured to amplify a difference between the sensed current and the control signal to generate a first output signal Vₒ₁;
a first controller configured to generate a first gate driver signal based on the first output signal; and
a first driver configured to generate a first complementary gate drive signal based on the first gate driver signal.

5. The negative reactance synthesizer of claim 4, wherein the current amplifier comprises:
an error amplifier;
a resistor R_{1_a1} having a first end connected to a negative input port of the error amplifier;
a capacitor C_{1_a1} having a first end connected to a second end of the resistor R_{1_a1} and a second end connected to an output port of the error amplifier; and
a capacitor C_{1_a2} having a first end connected to the negative input port of the error amplifier and a second end connected to the output port of the error amplifier.

6. The negative reactance synthesizer of claim 4, wherein the active-filter comprises:
an error amplifier;
a resistor R₁ having a first end connected to an input port of the active-filter and a second end connected to a negative input port of the error amplifier;
a resistor R₂ having a first end connected to a negative input port of the error amplifier and a second end connected to an output port of the error amplifier; and
a capacitor C₁ connected in parallel with the resistor R₂.

7. The negative reactance synthesizer of claim 4, wherein the active-filter comprises:
an error amplifier;
a resistor R₃ having a first end connected to an input port of the active-filter and a second end connected to a negative input port of the error amplifier;
a resistor R₄ having a first end connected to the negative input port of the error amplifier and a second end connected to an output port of the error amplifier; and
a capacitor C₂ connected in parallel with the resistor R₃.

8. The negative reactance synthesizer of claim 4, wherein first control circuitry further comprises:
a resistor R_{1_f1} connected between the current sensor and a negative input port of the current amplifier; and
a resistor R_{1_f2} connected between the multiplier and a positive input port of the current amplifier.

9. The negative reactance synthesizer of claim 1, wherein the second control circuitry comprises:
a voltage sensor configured to sense the stack-up DC voltage V_{E} and generate a sensed voltage proportional to the stack-up DC voltage V_{E};
a voltage amplifier configured to amplify a difference between the sensed voltage and a second reference signal, and generate a second output signal;
a second controller configured to generate a second gate driver signal based on the second output signal; and
a second driver configured to derive a second complementary gate drive signal from the second gate driver signal.

10. The negative reactance synthesizer of claim 9, wherein
the voltage sensor comprises:
a sensing resistor R_{2_v1} having a first end connected to the positive terminal of the output port of the second converter;
a sensing resistor R_{2_v2} having a first end connected to a second end of the sensing resistor R_{2_v1}; and
the sensed voltage is generated at a connection node between the sensing resistor R_{2_v1} and the sensing resistor R_{2_v2}.

11. The negative reactance synthesizer of claim 9, wherein the voltage amplifier comprises:
an error amplifier;
a resistor R_{2_a1} having a first end connected to a negative input port of the error amplifier; and
a capacitor C_{2_a1} having a first end connected to a second end of the resistor R_{2_a1} and a second end connected to an output port of the error amplifier.

12. The negative reactance synthesizer of claim 11, wherein the second control circuitry further comprises:
a resistor R_{2_f1} connected between the second reference signal and a negative input port of the voltage amplifier; and
a resistor R_{2_f2} connected between the voltage sensor and a positive input port of the voltage amplifier.
